(19) United States
(12) Patent Application Publication
(10) Pub. No.: US 2008/0029854 A1
(43) Pub. Date: Feb. 7, 2008

(54) CONDUCTIVE SHIELDING PATTERN AND SEMICONDUCTOR STRUCTURE WITH INDUCTOR DEVICE

(75) Inventors: Cheng-Chou Hung, Hsinchu County (TW); Hua-Chou Tseng, Hsinchu (TW); Yu-Chia Chen, Taipei City (TW); Victor-Chiang Liang, Hsinchu City (TW); Cheng-Wen Fan, Tainan City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/462,269

(22) Filed: Aug. 3, 2006

(51) Int. Cl. H01L 23/552

(52) U.S. Cl. 257/659

(57) ABSTRACT

The invention is directed to a conductive shielding pattern for shielding a inductor device. The conductive shielding pattern comprises a plurality of conductive layers and a plurality of diffusion regions. The conductive layers are located on a substrate. The diffusion regions are located in the substrate and the conductive layers and the diffusion regions are arranged alternatively and are free ends respectively.

### BACKGROUND OF THE INVENTION

1. Field of Invention

The present invention relates to a semiconductor device. More particularly, the present invention relates to a conductive shielding pattern and a semiconductor device having an inductor device.

2. Description of Related Art

In the integrated circuit, the inductor device is an importance device. Generally, the inductor device is a round shape or square shape spiral metal coil. Moreover, the inductor device can be widely used. For the high frequency application field, it demands relatively high quality of the inductor device. That is, the inductor device possesses relatively high quality factor Q in this application field. The factor Q mentioned above is defined according to:

Q=ω₀×L/R (1), wherein ω₀ indicates the resonant angular frequency of the inductor device, R indicates the resistance of the inductor device and L indicates the inductance of the metal coil. Since the inductor device is located close to the silicon substrate, the silicon substrate turns to be a conductor to consume a large amount of energy to lower the quality of the inductor device under the high frequency of the high frequency device.

Therefore, in order to solve the problem mentioned above and increase the quality and factor Q of the inductor device, the shielding effect of the conductive layer is utilized and the conductive layer is used to separate the substrate from the inductor device as illustrated in the United State Patten labeled U.S. Pat. No. 5,760,456. In the pattern mentioned above, since there is a conductive layer located between the inductor device and the substrate, effect of the substrate resistance R_{sub} to the inductor device can be excluded. Meanwhile, the low resistance path from the electric field termination to the substrate grounded terminal can be effectively replace the substrate resistance R_{sub}.

Additionally, because the pattern of the conventional inductor device is spiral type, the eddy current is easily induced within the conductive layer. Accordingly, when the conductive layer is really close to the inductor device, the eddy current within the conductive layer would obstruct and counteract the magnetic field generated by the spiral inductor device. Hence, the inductance of the spiral inductor device is decreased and the parasitic capacitance Cₒₓ is increased.

Therefore, the United State Patten labeled U.S. Pat. No. 5,760,456 further provides another conductive pattern to avoid the generation of the eddy current. The conductive pattern is formed by improving the original conductive layer with entire surface to be a conductive layer with an irregular pattern or comb type pattern with no circuit therein.

Currently, another conductive shielding pattern used to block the inductor device from the silicon substrate is developed in the United State Patten labeled U.S. Pat. No. 6,593,838. FIG. 1 is a top view showing the conductive shielding pattern provided by the pattern aforementioned.

As shown in FIG. 1, the conductive shielding pattern 100 is a single-layered conductive pattern located between the inductor device and the silicon substrate. The main body of the single-layered conductive pattern is a radiation structure. Moreover, the conductive shielding pattern 100 only possesses an intersection point 110 at the center of the pattern and none of the channels is a closed circuit.

Additionally, the aforementioned pattern further discloses a double-layered conductive shielding pattern as shown in FIGS. 2A, 2B and 2C which are top views of the other conductive shielding patterns of the inductor device.

As shown in FIG. 2A the main body 200 of the double-layered conductive shielding pattern is a cross shape. As shown in FIG. 2B, the separated conductive material can be used as the radiation branch 210. Alternatively, as shown in FIG. 2C, a conductive material intersecting the center 220 of the main body 200 can be used as the radiation branch 230.

To further improve the quality and the factor Q of the inductor device, the structure of the aforementioned conductive shielding pattern still need to be modified.

### SUMMARY OF THE INVENTION

Accordingly, at least one objective of the present invention is to provide a conductive shielding pattern capable of improving the quality and the factor Q of the inductor device.

At least another objective of the present invention is to provide a semiconductor device having inductor device capable of providing relatively high factor Q.

To achieve these and other advantages and in accordance with the purpose of the invention, as embodied and broadly described herein, the invention provides a conductive shielding pattern for shielding a inductor device. The conductive shielding pattern comprises a plurality of conductive layers and a plurality of diffusion regions. The conductive layers are located on a substrate. The diffusion regions are located in the substrate and the conductive layers and the diffusion regions are arranged alternatively and are free ends respectively.

According to the conductive shielding pattern described in one embodiment of the present invention, the arrangement of the conductive layers and the diffusion regions is an edge-to-edge arrangement.

According to the conductive shielding pattern described in one embodiment of the present invention, each conductive layer is apart from each diffusion region for a distance.

According to the conductive shielding pattern described in one embodiment of the present invention, each conductive layer partially overlaps with each diffusion region.

According to the conductive shielding pattern described in one embodiment of the present invention, the aforementioned conductive layer are made of polysilicon or metal.

According to the conductive shielding pattern described in one embodiment of the present invention, the aforementioned material of the conductive layers is selected from a group consisting of copper, gold, nickel, aluminum and tungsten.

According to the conductive shielding pattern described in one embodiment of the present invention, the aforementioned conductive shielding pattern further comprises a first metal line and a second metal line. The first metal line is located on the conductive layers and connected the conductive layers to each other, wherein a first pattern composed of the conductive layers and the first metal line is a free end. The second metal line is located on the diffusion regions and connected the diffusion regions to each other, wherein a second pattern composed of the diffusion regions and the second metal line is a free end.

The invention further provides a semiconductor structure having an inductor device. The semiconductor structure comprises a substrate, an inductor device, a conductive shielding pattern and an insulating layer. The inductor device is located over the substrate and the conductive shielding pattern is located under the inductor device and used to shield the inductor device. The conductive shielding pattern comprises a plurality of conductive layers and a plurality of diffusion regions located in the substrate, wherein the conductive layers and the diffusion regions are alternatively arranged and are free ends. The insulating layer is located between the conductive shielding pattern and the inductor device.

According to the semiconductor device described in one embodiment of the present invention, the aforementioned inductor device comprises round shape spiral inductor device and square shape spiral inductor device.

According to the semiconductor device described in one embodiment of the present invention, the arrangement of the conductive layers and the diffusion regions is an edge-to-edge arrangement.

According to the semiconductor device described in one embodiment of the present invention, each conductive layer is apart from each diffusion region for a distance.

According to the semiconductor device described in one embodiment of the present invention, each conductive layer partially overlaps with each diffusion region.

According to the semiconductor device described in one embodiment of the present invention, the aforementioned conductive layer are made of polysilicon or metal.

According to the semiconductor device described in one embodiment of the present invention, the aforementioned material of the conductive layers is selected from a group consisting of copper, gold, nickel, aluminum and tungsten.

According to the semiconductor device described in one embodiment of the present invention, the aforementioned conductive shielding pattern further comprises a first metal line and a second metal line. The first metal line is located on the conductive layers and connected the conductive layers to each other, wherein a first pattern composed of the conductive layers and the first metal line is a free end. The second metal line is located on the diffusion regions and connected the diffusion regions to each other, wherein a second pattern composed of the diffusion regions and the second metal line is a free end.

In the present invention, since the alternative arrangement of the conductive layers and the diffusion regions is the conductive shielding pattern for shielding the inductor device, the permeance interference of the substrate to the inductor device is decreased and the performance of the chip is increased. Meanwhile, the eddy current is hardly generated by the novel conductive shielding pattern so that the inductance of the inductor device is maintained and the parasitic capacitance is decreased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a conventional conductive shielding pattern.

FIGS. 2A through 2C are top views showing other conventional conductive shielding patterns.

FIG. 3A is a top view showing a conductive shielding pattern according to one embodiment of the present invention.

FIG. 3B is a cross-sectional view of FIG. 3A along line B-B.

FIG. 3C is an enlarged diagram of a C region of FIG. 3A.

FIG. 4 is an alternative type of FIG. 3B.

FIG. 5 is an alternative type of FIG. 3B.

FIG. 6A is a top view showing a semiconductor structure according to another embodiment of the present invention.

FIG. 6B is a cross-sectional view of FIG. 6A along line B-B.

FIG. 7 is a frequency-versus-factor Q plot diagram according to the conductive shielding structures of the present invention and two conventional conductive shielding structures.

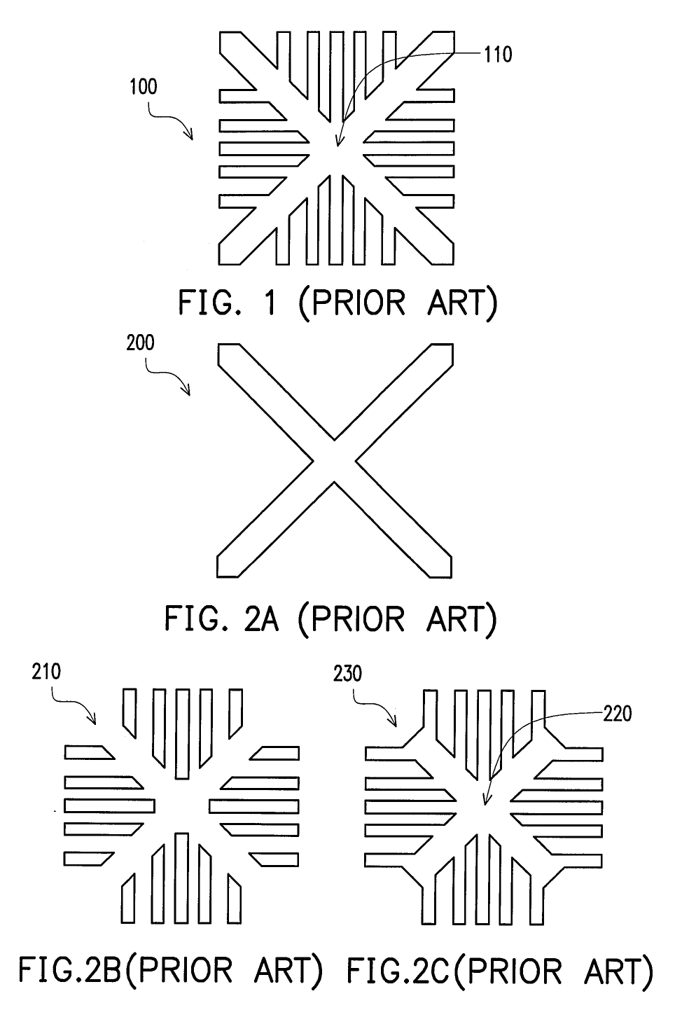

### DESCRIPTION OF THE PREFERRED EMBODIMENTS

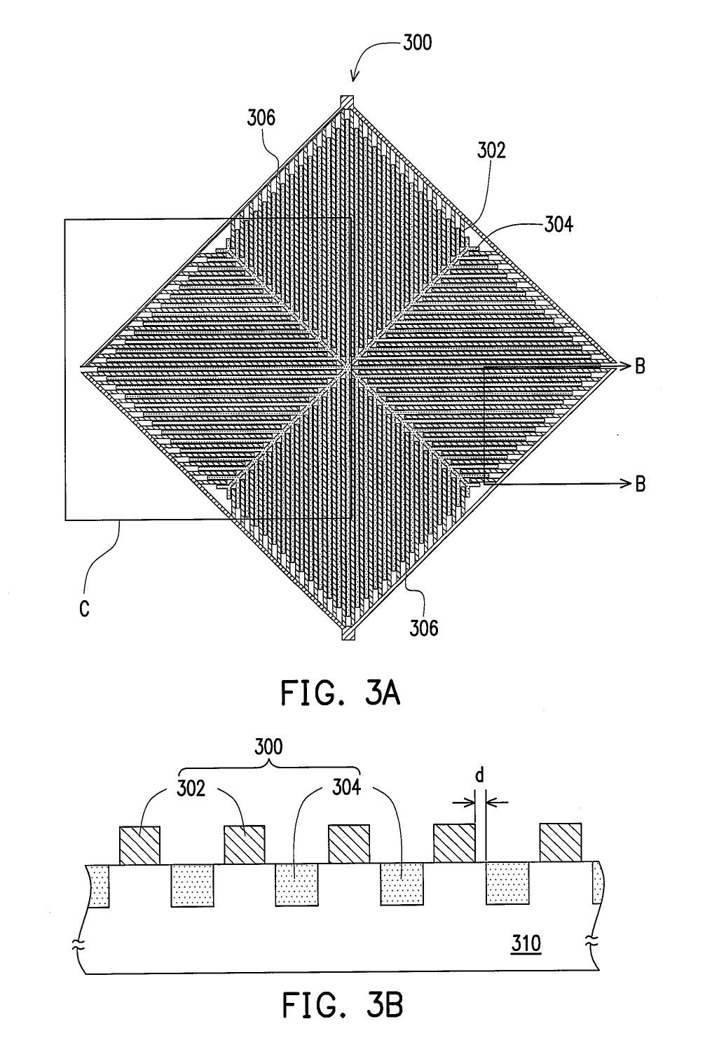

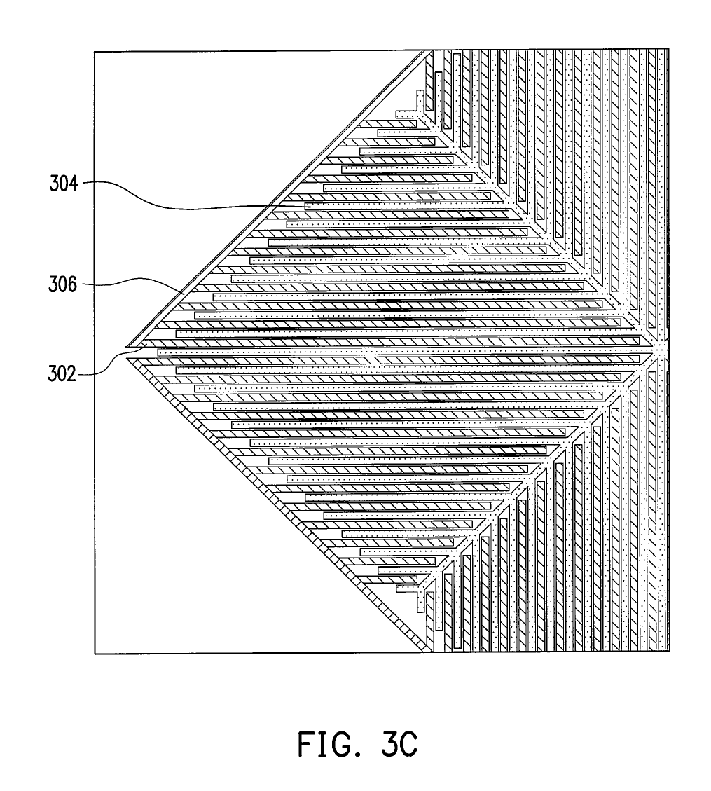

FIG. 3A is a top view showing a conductive shielding pattern according to one embodiment of the present invention. FIG. 3B is a cross-sectional view of FIG. 3A along line B-B. FIG. 3C is an enlarged diagram of a C region of FIG. 3A.

As shown in FIG. 3A together with FIGS. 3B and 3C, in this embodiment, the conductive shielding pattern 300 is used to shield an inductor device (not shown). This conductive shielding pattern 300 is composed of alternatively arranged conductive layers 302 and diffusion regions 304. The conductive layers are made of polysilicon or metal such as copper, gold, nickel, aluminum and tungsten. The conductive layers 302 are located on the substrate 310 and the diffusion regions 304 are located in the substrate 310. The conductive layers 302 and the diffusion regions 304 are free ends. Moreover, the conductive shielding pattern 300 of this embodiment further comprises several metal lines 306 located conductive layers 302 and the diffusion regions 304 respectively and connected the conductive layers 302 to each other and connected the diffusion regions 304 to each other. The metal lines 306 can be a metal layer, which is so-called metal 1 layer in the semiconductor process technology, used to form the gate electrode, source and drain of the semiconductor device. Alternatively, the metal lines 306 can be an additional metal layer over the metal 1 layer. Furthermore, the pattern composed of the metal lines 306 and the conductive layers 302 is a free end. The pattern composed of the metal lines 306 and the diffusion regions 304 is a free end as well. In this embodiment, each conductive layer 302 is apart from each diffusion region 304 for a distance d.

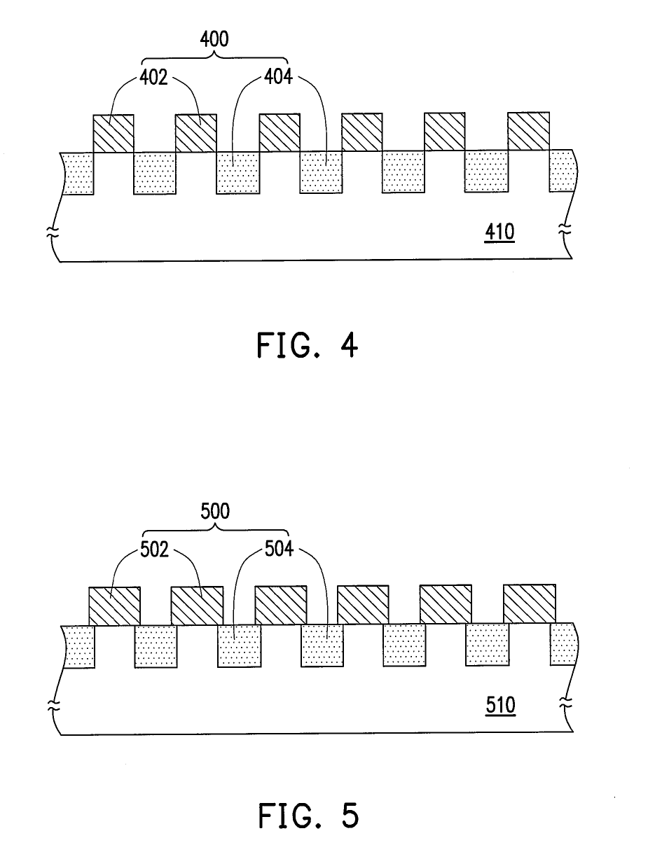

FIG. 4 is an alternative type of FIG. 3B. FIG. 5 is an alternative type of FIG. 3B. As shown in FIG. 4, the arrangement of the conductive layers 402 and the diffusion regions 404 is an edge-to-edge arrangement. Alternatively, in FIG. 5, the conductive layers 502 partially overlap the diffusion regions 504 respectively.

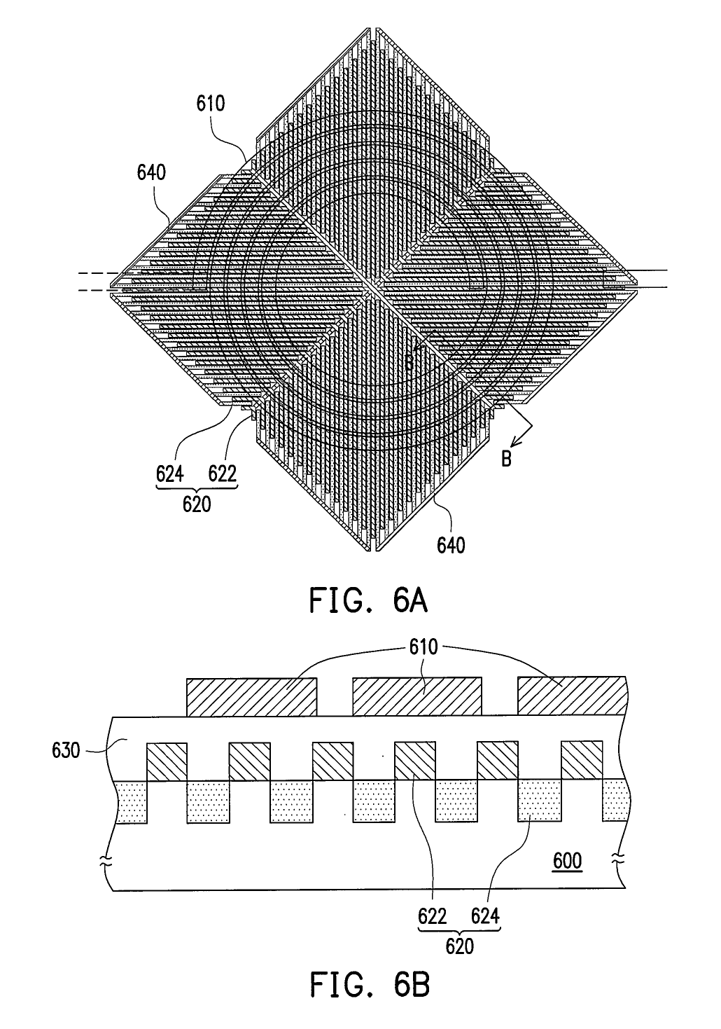

FIG. 6A is a top view showing a semiconductor device according to another embodiment of the present invention. FIG. 6B is a cross-sectional view of FIG. 6A along line B-B.

As shown in FIG. 6A and FIG. 6B, the semiconductor structure of this embodiment comprises a substrate 600 and an inductor device 610, a conductive shielding pattern 620 and an insulating layer 630 over the substrate 600. The inductor device 610 can be, for example but not limited to, a round shape spiral inductor device as shown in FIG. 6A and FIG. 6B or a square shape spiral inductor device. The conductive shielding pattern 620 is located under the inductor device 610 and used to shield the inductor device 610. The conductive shielding pattern 620 comprises several conductive layers 622 and diffusion regions 624. The conductive layers 622 are located on the substrate 600 and the diffusion regions 624 are located in the substrate 600. The conductive layers 622 and the diffusion regions 624 are alternatively arranged and the conductive layers 622 and the diffusion regions 624 are free ends. Moreover, the insulating layer 630 is located between the conductive shielding pattern 620 and the inductor device 610. Furthermore, the arrangement of the conductive layers 622 and the diffusion regions 624 can be, for example but not limited to, an edge-to-edge arrangement or a partially overlapped arrangement.

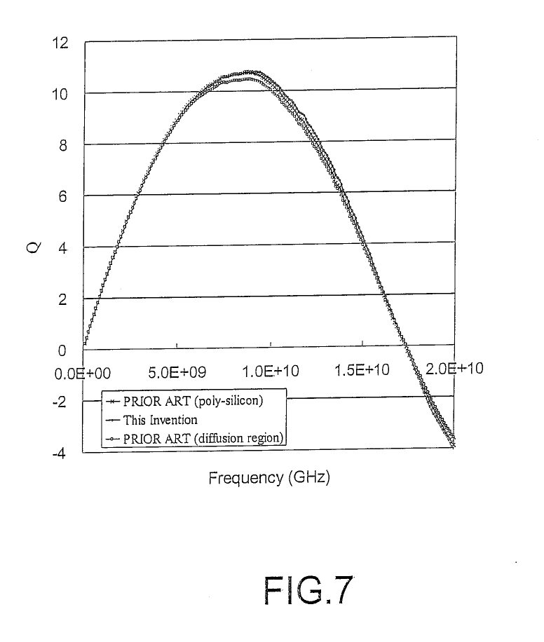

In order to prove the efficiency of the present invention, FIG. 7 is a frequency-versus-factor Q plot diagram according to the conductive shielding structures of the present invention and two conventional conductive shielding structures. The conventional conductive shielding patterns are similar to what shown in FIG. 3 but one is single-material (i.e. poly-silicon) conductive shielding pattern, and the other is to utilize diffusion regions as the conductive shielding pattern.

As shown in FIG. 7, the factor Q of the inductor device with the use of the conductive shielding pattern according to the present invention is larger than those of the inductor devices with the uses of the convention conductive shielding patterns. Hence, the factor Q of the inductor is improved by using the conductive shielding pattern according to the present invention.

Altogether, in the conductive shielding pattern according to the present invention, since the conductive layers and the diffusion regions are alternatively arranged, the permeance interference of the substrate to the inductor device is decreased and the factor Q of the inductor device is increased. Meanwhile, no eddy current is generated by the conductive shielding pattern so that the inductance of the inductor device is maintained and the parasitic capacitance is decreased.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A conductive shielding pattern for shielding a inductor device, the conductive shielding pattern comprising:
a plurality of conductive layers located on a substrate; and
a plurality of diffusion regions located in the substrate, wherein the conductive layers and the diffusion regions are arranged alternatively and are free ends respectively.

2. The conductive shielding pattern of claim 1, wherein the arrangement of the conductive layers and the diffusion regions is an edge-to-edge arrangement.

3. The conductive shielding pattern of claim 1, wherein each conductive layer is apart from each diffusion region for a distance.

4. The conductive shielding pattern of claim 1, wherein each conductive layer partially overlaps with each diffusion region.

5. The conductive shielding pattern of claim 1, wherein the conductive layer are made of polysilicon or metal.

6. The conductive shielding pattern of claim 5, wherein the material of the conductive layers is selected from a group consisting of copper, gold, nickel, aluminum and tungsten.

7. The conductive shielding pattern of claim 1 further comprising:
a first metal line located on the conductive layers and connected the conductive layers to each other, wherein a first pattern composed of the conductive layers and the first metal line is a free end; and
a second metal line located on the diffusion regions and connected the diffusion regions to each other, wherein a second pattern composed of the diffusion regions and the second metal line is a free end.

8. A semiconductor structure having an inductor device, comprising:
a substrate;
a inductor device located over the substrate;
a conductive shielding pattern located under the inductor device and used to shield the inductor device, wherein the conductive shielding pattern comprises:
a plurality of conductive layers; and
a plurality of diffusion regions located in the substrate, wherein the conductive layers and the diffusion regions are alternatively arranged and are free ends; and
an insulating layer located between the conductive shielding pattern and the inductor device.

9. The semiconductor device of claim 8, wherein the inductor device comprises round shape spiral inductor device and square shape spiral inductor device.

10. The semiconductor device of claim 8, wherein the arrangement of the conductive layers and the diffusion regions is an edge-to-edge arrangement.

11. The semiconductor device of claim 8, wherein each conductive layer is apart from each diffusion region for a distance.

12. The semiconductor device of claim 8, wherein each conductive layer partially overlaps with each diffusion region.

13. The semiconductor device of claim 8, wherein the conductive layer are made of polysilicon or metal.

14. The semiconductor device of claim 13, wherein the material of the conductive layers is selected from a group consisting of copper, gold, nickel, aluminum and tungsten.

15. The semiconductor device of claim 8 further comprising:
a first metal line located on the conductive layers and connected the conductive layers to each other, wherein a first pattern composed of the conductive layers and the first metal line is a free end; and
a second metal line located on the diffusion regions and connected the diffusion regions to each other, wherein a second pattern composed of the diffusion regions and the second metal line is a free end.
